(19) United States
(12) Patent Application Publication
(10) Pub. No.: US 2007/0240749 A1
(43) Pub. Date: Oct. 18, 2007

(54) Porous Thermoelectric Material and Process for Producing the Same

(75) Inventor: Michitaka Ohtaki, Fukuoka (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: JAPAN SCIENCE AND TECHNOLOGY AGENCY, Kawaguchi-shi (JP)

(21) Appl. No.: 10/593,556

(22) PCT Filed: Mar. 22, 2005
(86) PCT No.: PCT/JP05/05088

§ 371 Date: Sep. 20, 2006

(30) Foreign Application Priority Data
Mar. 22, 2004 (JP) 2004-083713

(51) Int. Cl. H01L 35/00

(52) U.S. Cl. 136/200

(57) ABSTRACT

In a thermoelectric conversion material composed of a porous material, continuous electrical conduction paths are provided by forming voids in the form of independent closed pores or independent closed air tubes inside the material. For example, in producing a sintered body of a thermoelectric material, microparticles having a particle diameter of 1 μm or less serving as a void-forming agent are mixed in a base powder, and in sintering, the sintering atmosphere or sintering temperature is controlled so that after the densification of a solid part formed by sintering the base powder proceeds, the microparticles of the void-forming agent are gasified, thereby producing a porous thermoelectric material having a structure in which minute independent closed pores having an average pore diameter of 1 μm or less are dispersed.

### TECHNICAL FIELD

The present invention relates to a porous thermoelectric material in which the thermoelectric figure of merit Z is improved by forming independent closed pores or independent closed air tubes while continuous electrical conduction paths are ensured inside the material, and a process for producing the same.

### BACKGROUND ART

Having a stable reserve of energy for the future is the greatest problem mankind faces. Thermoelectric power generation has attracted attention as an environment-conscious energy-saving technique in which unutilized energy such as industrial waste heat can be converted into electrical energy and recovered. All the thermoelectric materials that are practically used now, such as Bi₂Te₃, are nonoxides. Problems such as environmental pollution caused by heavy elements constituting the thermoelectric materials; the degradation of thermoelectric elements; and the costs required for the raw materials, refining, production, and recycle have not yet been solved. Oxide-based thermoelectric materials have excellent oxidation resistance, heat resistance, and chemical stability, can be easily produced thus realizing a process requiring a low cost, and can be practically used over a wide range of applications. Therefore, the improvement in the performance of such thermoelectric materials has attracted a great deal of interest. The present inventor and others have developed ZnO-based oxide and NaCo₂O₄-based oxide thermoelectric materials, and have applied patents relating to the invention of the materials (Patent Documents 1 and 2).

A known method of increasing the thermoelectric figure of merit of thermoelectric materials is a method of making the materials porous. Examples of the methods or such thermoelectric materials include a method of adding adamantane or a mixture of adamantane and trimethylene norbornane to a powder of a metal alloy and then sintering the mixture to produce a porous thermoelectric element (Patent Document 3), a thermoelectric conversion material in which a plurality of voids having a certain size and disposed so as to have a certain interval to the extent that the interaction with phonons or electrons becomes significant are introduced into the inside of a semiconductor material to make the material porous, and the thermoelectric conversion figure of merit is increased by a decrease in the thermal conductivity and an increase in the thermoelectric power due to the decrease in the density (Patent Document 4), a thermoelectric conversion material that is composed of a sintered body containing at least one type of inorganic compound having a work function of 4 eV or less and an Al₂O₃-type oxide having a C-rare-earth structure and that has a porosity in the range of 3% to 90% (Patent Document 5), a thermoelectric conversion element composed of a sintered body having a relative density in the range of 90% to 98% in which pores having an average diameter in the range of 1 to 5 μm are distributed (Patent Document 6), and a method of producing a thermoelectric conversion material composed of an AₓCoO₃ crystal (wherein A represents an alkali metal element) having minute pores with an average pore diameter of 100 nm or less including a heat treatment in an oxidizing atmosphere or air (Patent Document 7).
Patent Document 1: Japanese Unexamined Patent Application Publication No. 8-186293
Patent Document 2: Japanese Unexamined Patent Application Publication No. 12-068721
Patent Document 3: Japanese Examined Patent Application Publication No. 3-47751
Patent Document 4: Japanese Patent No. 2958451
Patent Document 5: Japanese Unexamined Patent Application Publication No. 11-97751
Patent Document 6: Japanese Unexamined Patent Application Publication No. 2002-223013
Patent Document 7: Japanese Unexamined Patent Application Publication No. 2003-229605

### DISCLOSURE OF INVENTION

### Problems to be Solved by the Invention

In the thermoelectric conversion using a thermoelectric phenomenon of a solid, it is necessary that the figure of merit Z represented by Z=S²σ/κ is high wherein σ represents the electrical conductivity of a solid element material, S represents the Seebeck coefficient, and κ represents the thermal conductivity. Accordingly, a high electrical conductivity σ and a low thermal conductivity κ are required for the element material. However, in known techniques that have been used for decreasing the thermal conductivity κ of a material, for example, in the techniques of (1) partially replacing the crystal lattice points of the material with a heavy element, (2) dispersing microparticles into the material, and (3) making the material porous, when the thermal conductivity κ is decreased, the electrical conductivity σ also decreases at the same time. Therefore, these techniques cannot be applied to thermoelectric materials.

According to a method of producing the material described in Patent Document 4 (Japanese Patent No. 2958451), a single crystal substrate or the like is etched by an anodic reaction to be porous. According to a method of producing the material described in Patent Document 5 (Japanese Unexamined Patent Application Publication No. 11-97751), an organic binder is added and mixed with a base powder, and the mixture is formed and then sintered. Thus, the resulting material becomes porous.

However, in the known method using burn-off or vaporization of an organic substance caused by sintering, or the technique for producing a porous material using etching or the like, since a large number of pores opening to the outside are formed, the continuity of the solid part is disconnected at the air gaps of the open pores. Consequently, continuous electrical conduction paths cannot be ensured. Accordingly, as the material becomes porous, the electrical conductivity σ is markedly decreased. As a result, the figure of merit is not increased. The thermoelectric material produced by the method described in Patent Document 5 operates on the basis of electron gas conduction caused by thermionic emission in continuous open pores. Therefore, a desired effect can be achieved only in vacuum.

### Means for Solving the Problems

The present inventor has found the following: In a thermoelectric conversion material including a porous material composed of a semiconductor material, an oxide material, or the like, the thermoelectric conversion material is composed of a porous material that does not include pore parts opening to the outside or connected to each other, and continuous electrical conduction paths are provided inside the material. Thereby, the figure of merit Z can be improved using the same element material while the electrical conductivity is negligibly changed.

Namely, the present invention provides a thermoelectric conversion material composed of a porous material, wherein continuous electrical conduction paths are provided by forming voids in the form of independent closed pores or independent closed air tubes inside the material.

FIG. 1 includes a graph showing an example of the difference in the temperature dependency of the electrical conductivity σ between the thermoelectric conversion material of the present invention and a known porous thermoelectric material and schematic views showing the difference between the structures thereof. In the known porous thermoelectric material, the paths of conduction electrons are separated because relatively large open pores are continuously provided. In contrast, in the present invention, a large number of minute independent closed pores or independent closed air tubes are dispersed in a dense matrix. Therefore, even when lattice vibration is scattered, the conduction electrons are not easily scattered, thus ensuring continuous electrical conduction paths.

In order to ensure the continuous electrical conduction paths inside the material, the voids must be independent closed pores or independent closed air tubes. As in the known material, even when the size of the pores is minute, open pores extending to the outside air cannot provide thermoelectric characteristics in the present invention. The average pore diameter of the independent closed pores or the average diameter of the independent closed air tubes is preferably 1 μm or less, more preferably 500 nm or less, and even more preferably 200 nm or less. The distance between nearest voids is preferably 5 μm or less, more preferably 500 nm or less, and even more preferably 200 nm or less. The void density is preferably 1×10¹⁰/cm³ or more, and more preferably 1×10¹⁴/cm³ or more.

The average pore diameter or the diameter is determined on the basis of the averages of the major axis and the minor axis of voids present in an area of 10 μm×10 μm using a polished surface image of a scanning electron microscope (SEM) with a magnification of 10,000. The distance between voids is determined on the basis of the average of the distance between the centers of two nearest voids. The void density is determined on the basis of the average of the distance between voids measured by the above method.

Closed pores or closed air tubes can be observed as the difference between the apparent density and true density of the material. Open pores can be observed as the difference between the bulk density and the apparent density. When the density of open pores is large, the measurement value of the surface area markedly increases. On the other hand, when the density of open pores or closed air tubes is small, the surface area does not markedly increase.

Furthermore, the present invention provides a method of producing the above-described thermoelectric conversion material, wherein, in producing a thermoelectric material composed of a sintered body, microparticles having a particle diameter of 1 μm or less or a fibrous substance having a diameter of 1 μm or less that serves as a void-forming agent (VFA) is mixed with a base powder, and in sintering this mixture, the mixed powder is sintered in an atmosphere of an inert gas, a reducing gas, or a controlled oxidizing gas so that after the densification of a solid part formed by sintering the base powder proceeds, the void-forming agent is removed, thereby forming independent closed pores or independent closed air tubes, in which parts that have been excluded by the volume of the void-forming agent are not connected to each other, in a continuous dense matrix.

The present invention also provides a method of producing the above-described thermoelectric conversion material, wherein, in producing a thermoelectric material composed of a sintered body, microparticles having a particle diameter of 1 μm or less or a fibrous substance having a diameter of 1 μm or less that serves as a void-forming agent is mixed with a base powder, and in sintering this mixture, the mixed powder is sintered at a temperature lower than the temperature at which the void-forming agent is gasified, dissolved, or melted so that after the densification of a solid part formed by sintering the base powder proceeds, the void-forming agent is removed, thereby forming independent closed pores or independent closed air tubes, in which parts that have been excluded by the volume of the void-forming agent are not connected to each other, in a continuous dense matrix.

The void-forming agent may be removed by gasification, dissolution, or melting. Preferably, after the densification of the solid part proceeds, sintering is performed at a temperature higher than the temperature at which the void-forming agent is gasified. Thus, the void-forming agent may be removed by gasification.

In the present invention, it is important that continuous electrical conduction paths are ensured by the structure in which a continuous matrix is ensured in the inside of the material and independent closed pores or independent closed air tubes are provided inside the material. A small number of pores opening to the outside do not cause a problem. A method of producing such a structure is not limited to the above methods. Alternatively, a method in which a porous material having pores opening to the outside is produced, and the pores disposed on the surface are closed by machining, a chemical reaction, an application of a sealing agent, or the like may be employed. Alternatively, a method in which a porous material is produced by laminating thin films, and pores of the laminate that open to the outside are closed by further laminating thin films composed of a non-porous material on the top surface and the bottom surface of the laminate may be employed.

Since most of the thermoelectric material obtained by the method of producing a thermoelectric material of the present invention is composed of a continuous dense body, the electrical conduction paths are not disconnected. Furthermore, the decrease in the cross-section of the thermoelectric material due to the presence of the minute closed pores or open air tubes is negligible. Therefore, the thermal conductivity κ can be markedly decreased by the dispersion of the minute closed pores or open air tubes, while the electrical conductivity σ is hardly decreased compared with a dense sintered body that does not contain minute closed pores or open air tubes. Consequently, an effect of significantly improving the figure of merit Z can be achieved.

It is known that, in porous oxides, the Seebeck coefficients S have a characteristic maximal peak in the temperature dependency thereof. It is believed that this is an effect of fine pores. In the present invention, a maximal peak of the Seebeck coefficient S is similarly observed in the material that is processed to be porous, resulting in an effect of further improving the figure of merit Z.

According to the ZnO-based oxide thermoelectric material that has been developed by the present inventor and others, electrically, the thermoelectric performance is the maximum among oxides and is equal to that of existing materials. However, since the ZnO-based oxide thermoelectric material has a very high thermal conductivity, the overall performance is 30% of the level required for practical use. In the present invention, a closed pore structure or a closed air tube (nanovoid) structure is introduced in which Zn_{0.98}Al_{0.02}O (Zn-Al), which exhibits the most excellent electrical performance among ZnO-based materials, is used as the parent phase and minute independent closed pores or independent closed air tubes are dispersed in the dense matrix. Thereby, the phonon thermal conductivity is decreased, and an improvement in the thermoelectric performance has been realized. In the thermal conductivity of a ZnO-based material, a contribution by phonons is dominant. Therefore, only the thermal conductivity is decreased by a selective enhancement of phonon scattering, and thus the performance can be improved to the level required for practical use.

### Advantages of the Invention

According to the thermoelectric material of the present invention, the figure of merit Z can be improved using the same element material while the electrical conductivity is negligibly changed. Consequently, this thermoelectric material enables power generation using heat in a field in which known thermoelectric materials have not been successfully used to date in view of profitability. Thus, the thermoelectric material of the present invention contributes to an improvement in the energy utilization efficiency and a reduction in the carbon dioxide emission. Furthermore, since the thermoelectric material of the present invention is not affected by the external atmosphere during use, this material can be used in air without problems.

### Best Mode for Carrying Out the Invention

A typical method of producing a thermoelectric material of the present invention is a method of mixing a void-forming agent (VFA) that can be removed from a sintered body by gasification, dissolution, melting, or the like, for example, organic polymer microparticles or carbon microparticles having a particle diameter of 1 μm or less, or a fibrous substance having a diameter of 1 μm or less, such as a fiber of cellulose, nylon, polyester, or carbon, with a base powder of the thermoelectric material, and sintering the mixture.

For example, when the mixed powder is molded and then sintered, the sintering of the material is conducted while the VFA is maintained without gasification at a temperature lower than the temperature at which the VFA is gasified and/or in an atmosphere in which the VFA is not easily gasified. For an oxidizing VFA, the atmosphere in which the VFA is not easily gasified is formed by an inert gas, a reducing gas, or a controlled oxidizing gas such as an oxidizing (oxygen-containing) gas in which the oxygen partial pressure is lower than that of the air.

Thus, after the densification of a solid part composed of the sintering material proceeds, the VFA is gasified. Thereby, a porous thermoelectric material having a structure in which a large number of minute independent closed pores having a particle diameter of 1 μm or less or independent closed air tubes that have no parts continuing to the outside are dispersed inside a continuous dense solid matrix can be produced. After the densification of the solid part proceeds, gasification can be satisfactorily conducted at a sufficiently high temperature or by changing the atmosphere. Alternatively, for example, the same effect can be achieved by successively increasing the temperature in a nitrogen gas atmosphere instead of discontinuously changing the temperature or the atmosphere in the course of the sintering.

When microparticles composed of an organic polymer or carbon, or a fibrous substance is mixed with a base powder and then simply sintered without employing the above sintering method, the microparticles or the fibrous substance is gasified before the sintering proceeds. Consequently, when the size of the microparticles or the fibrous substance is large or the amount of the microparticles or the fibrous substance added is large, a large number of open pores or open air tubes are formed. In such a case, the electrical conductivity is markedly decreased, resulting in a poor performance.

In the method of producing the thermoelectric material of the present invention, the target thermoelectric material is not limited to oxide-based materials. The thermoelectric material may be an alloy-based material as long as the material can be sintered in an inert atmosphere or a reducing atmosphere. When the particle diameter or the diameter of the VFA exceeds 1 μm, it is difficult to ensure the continuity with the dense matrix. The lower limit in the size of VFA is limited in view of the ease of availability as a VFA, the ease of mixing with the raw material, and the like. It is more effective that a large number of small pores are provided in the sintered body. The VFA is gasified in an oxidizing atmosphere at a high temperature. For example, the VFA is gasified by reacting with oxygen in an oxidizing atmosphere at 200° C. or higher. The gasified VFA is diffused outside the sintered body to be dissipated, thereby forming a large number of minute closed pores or open air tubes in which parts that have been excluded by the volume of the VFA are not connected to each other. Therefore, the VFA is not limited to microparticles composed of an organic polymer or carbon, or a fibrous substance and may be other substances as long as the substance disappears in an oxidizing atmosphere at a high temperature.

The volume ratio of the VFA to the mixture containing the raw material is in the range of 1% to 50%, and preferably in the range of 5% to 20%. When the amount of VFA is less than 1 volume percent, the number of closed pores or open air tubes formed is small and thus the volume ratio of the void parts is small. Consequently, the whole material substantially serves as a dense sintered body, and the effect of adding the VFA is not achieved.

In the method of producing the thermoelectric material of the present invention, the sintered body is a continuous dense matrix, thereby the ratio of open pores or open air tubes is 15% or less, and more preferably 10% or less. The ratio of closed pores or open air tubes can be in the range of about 1% to 90% at which an effect can be observed. However, when the ratio exceeds the above range, undesirably, the electrical conductivity is decreased by one order of magnitude or more. The size of closed pores or open air tubes substantially corresponds to the size of the VFA used. A gas generated in the voids is diffused in the solid part during the process of sintering and densification at a high temperature and is dissipated from the inside of the sintered body. It is believed that, since the temperature is decreased to room temperature after the completion of the sintering, the inside of the closed pores or open air tubes is substantially maintained in a vacuum state.

For example, in the sintering of a ZnO-based oxide thermoelectric material, for example, polymethylmethacrylate (PMMA) particles are added as a void-forming agent (VFA), and sintering is performed under an inert atmosphere. Thereby, after the sintering of Zn-Al has proceeded to some extent, the VFA is gasified and dissipated. Consequently, a continuous dense matrix is formed, and a high electrical conductivity can be maintained. The Seebeck coefficients of the VFA-containing sample have a negative maximal value at about 900K, thereby improving the electrical performance. The dispersion of closed pores (nanovoids) having an average diameter of 145 nm can decrease the thermal conductivity by a maximum of 35%. The thermoelectric performance can be improved by introducing the nanovoid structure.

As another production method replaced with the above production method using a void-forming agent, in producing a thermoelectric material, a method of producing a porous material having pores opening to the outside as in a known method, and closing the pores disposed on the surface by machining, a chemical reaction, an application of a sealing agent, or the like may be employed.

In producing a thermoelectric material, a method of producing a porous material having pores opening to the outside, and closing the pores disposed on the surface by machining, a chemical reaction, an application of a sealing agent, or the like may be employed.

Furthermore, in producing a thermoelectric material composed of a sintered body, a method of applying a non-porous coating on the surface of a powder composed of a porous material having openings on the outside by machining, vapor deposition, a chemical reaction, an application of a sealing agent, or the like to prepare a base powder, and then sintering the powder may be employed. According to these production methods, a void-forming agent need not be mixed, and the sintering temperature and/or the sintering atmosphere is not limited.

### EXAMPLE 1

As a void-forming agent (VFA) for introducing closed pores, polymethylmethacrylate (PMMA) particles having average particle diameters of 150 nm, 430 nm, and 1,800 nm were added to an oxide powder (a mixture of ZnO and γ-alumina of Zn:Al=98:2) in amounts of 1, 5, 10, and 15 weight percent. These samples were sintered under a N₂ atmosphere at 1,400° C. for 10 hours.

### COMPARATIVE EXAMPLE 1

Sintering was performed under the same conditions as in Example 1 except that the atmosphere was air.

The following measurements were performed using the sintered bodies prepared in Example 1 and Comparative Example 1. The electrical conductivity σ was measured by a direct-current four-probe method, and the Seebeck coefficient S was measured in air by a steady method. A fracture surface and a polished surface were observed with an SEM. The sintered density of the sintered bodies was measured by the Archimedes method. The thermal conductivity was measured by a laser flash method.

FIG. 2 shows the temperature dependency of the electrical conductivity a of Zn_{0.98}Al_{0.02}O produced when the VFA having an average particle diameter of 150 nm was added in an amount of 10 weight percent in Example 1 and Comparative Example 1. The electrical conductivities a of both samples were substantially the same, and in the high-temperature area, the electrical conductivity σ of Zn-Al sintered under N₂ was slightly higher than that of Zn-Al sintered in air. As shown in FIG. 3, the Seebeck coefficient S was negative, and the sample sintered under N₂ had a negative local maximal at about 900K. FIG. 4 shows the power factor S²σ. The sample sintered under N₂ had a maximum higher than that of the sample sintered in air, which reflects the results shown in FIGS. 2 and 3.

FIG. 5 shows the thermal conductivity κ of Zn-Al, which is the parent phase, and a sample containing the VFA and sintered under N₂. The thermal conductivity κ of the sample containing the VFA decreased over the entire temperature range, and specifically, decreased by 35% at room temperature and by 30% at a high temperature of 760° C. FIG. 6 shows the thermoelectric figure of merit. Even when the VFA was added, the samples sintered in air were almost completely densified. On the other hand, in the sample sintered under N₂, as shown in the SEM image of the polished surface shown in FIG. 7, it was confirmed that minute closed pores (nanovoids) having a diameter in the range of 70 to 220 nm (average diameter 145 nm) were dispersed in a dense ZnO matrix.

### INDUSTRIAL APPLICABILITY

Since known thermoelectric materials have an insufficient value of the figure of merit Z, they have been used for power generation using heat, thermoelectric cooling, and the like in limited fields. Exhaust heat recovery power generation using the porous oxide thermoelectric material of the present invention can be realized, in particular, in the heat source of movable bodies such as automobiles, waste treatment plants, and other various industrial fields, in which the use of an inexpensive and safe oxide thermoelectric material has been desired, but has not been realized because of a low performance of the oxide material.

### BRIEF DESCRIPTION OF THE DRAWINGS

FIG. 1 includes a graph showing an example of the difference in the temperature dependency of the electrical conductivity σ between a thermoelectric conversion material of the present invention and a known porous thermoelectric material and schematic views showing the difference between the structures thereof.

FIG. 2 is a graph showing the temperature dependency of the electrical conductivity σ of Zn_{0.98}Al_{0.02}O produced in Example 1 and Comparative Example 1.

FIG. 3 is a graph showing the temperature dependency of the Seebeck coefficient of Zn_{0.98}Al_{0.02}O produced in Example 1 and Comparative Example 1.

FIG. 4 is a graph showing the temperature dependency of the power factor S²σ of Zn_{0.98}Al_{0.02}O produced in Example 1 and Comparative Example 1.

FIG. 5 is a graph showing the temperature dependency of the thermal conductivity κ of Zn_{0.98}Al_{0.02}O produced in Example 1 and Comparative Example 1.

FIG. 6 is a graph showing the temperature dependency of the thermoelectric figure of merit of Zn_{0.98}Al_{0.02}O produced in Example 1 and Comparative Example 1.

FIG. 7 is an SEM image as a drawing showing a polished surface of Zn_{0.98}Al_{0.02}O produced in Example 1.

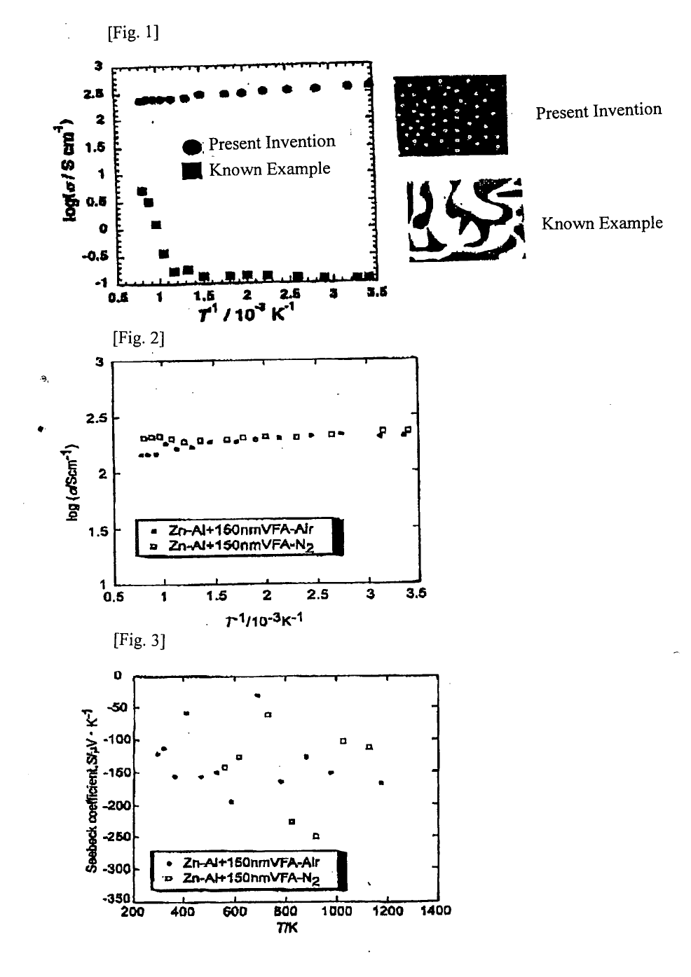

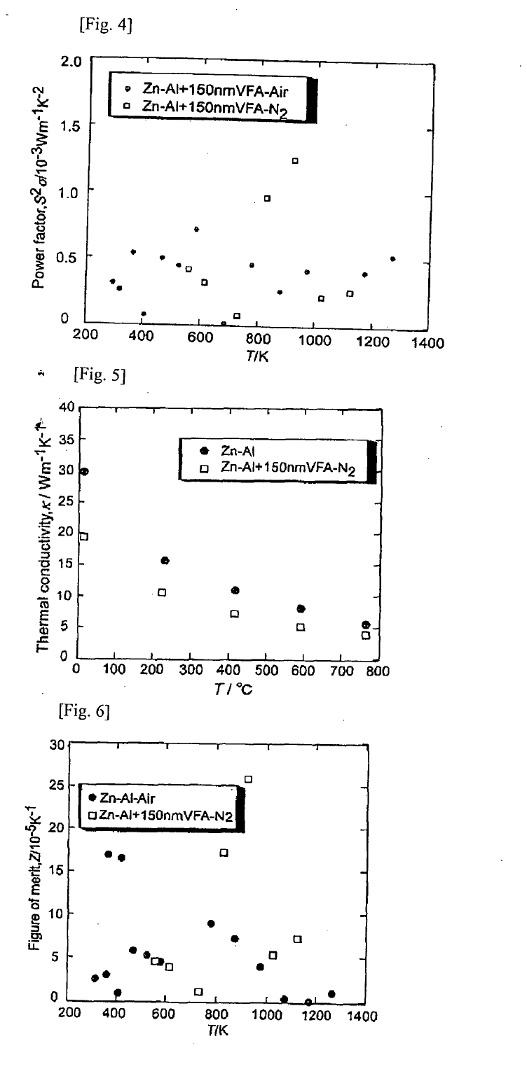

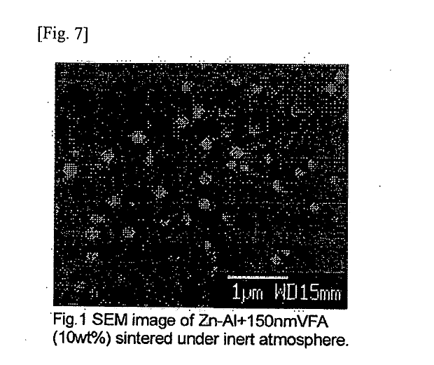

1. A method of producing a thermoelectric conversion material, wherein, in producing a thermoelectric conversion material comprising a porous material composed of a sintered body, microparticles having a particle diameter of 1 μm or less or a fibrous substance having a diameter of 1 μm or less that serves as a void-forming agent is mixed with a base powder, and in sintering this mixture, the mixed powder is sintered in an atmosphere of an inert gas, a reducing gas, or a controlled oxidizing gas so that after the densification of a solid part formed by sintering the base powder proceeds, the void-forming agent is removed from the sintered body, thereby producing a thermoelectric conversion material in which continuous electrical conduction paths composed of independent closed pores having an average pore diameter of 1 μm or less or independent closed air tubes having an average diameter of 1 μm or less are provided inside the material.

2. (canceled)

3. (canceled)

4. (canceled)

5. (canceled)

6. A method of producing a thermoelectric conversion material, wherein, in producing a thermoelectric material composed of a sintered body, microparticles having a particle diameter of 1 μm or less or a fibrous substance having a diameter of 1 μm or less that serves as a void-forming agent is mixed with a base powder, and in sintering this mixture, the mixed powder is sintered at a temperature lower than the temperature at which the void-forming agent is gasified, dissolved, or melted so that after the densification of a solid part formed by sintering the base powder proceeds, the void-forming agent is removed, thereby producing a thermoelectric conversion material in which continuous electrical conduction paths composed of independent closed pores having an average pore diameter of 1 μm or less or independent closed air tubes having an average diameter of 1 μm or less are provided inside the material.

7. The method of producing the thermoelectric conversion material according to claim 1, wherein the void-forming agent is removed by gasification, dissolution, or melting.

8. The method of producing the thermoelectric conversion material according to claim 1, wherein, after the densification of the solid part proceeds, sintering is performed at a temperature higher than the temperature at which the void-forming agent is gasified so that the void-forming agent is removed by gasification.

9. (canceled)

10. (canceled)

11. (canceled)

12. The method of producing the thermoelectric conversion material according to claim 6, wherein the void-forming agent is removed by gasification, dissolution, or melting.

13. The method of producing the thermoelectric conversion material according to claim 6, wherein, after the densification of the solid part proceeds, sintering is performed at a temperature higher than the temperature at which the void-forming agent is gasified so that the void-forming agent is removed by gasification.

14. The method of producing a thermoelectric conversion material according to claim 1, wherein the distance between nearest voids composed of the independent closed pores or the independent closed air tubes is 5 μm or less, and the density of the number of voids is 1×10¹⁰/cm³ or more.

15. The method of producing a thermoelectric conversion material according to claim 6, wherein the distance between nearest voids composed of the independent closed pores or the independent closed air tubes is 5 μm or less, and the density of the number of voids is 1×10¹⁰/cm³ or more.
